(19) United States
(12) Patent Application Publication
(10) Pub. No.: US 2010/0090352 A1
(43) Pub. Date: Apr. 15, 2010

(54) FLIP-CHIP SUBSTRATE AND METHOD OF MANUFACTURING THE SAME

(75) Inventors: Shigetsugu Muramatsu, Nagano-shi (JP); Yasuhiko Kusama, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/577,784

(22) Filed: Oct. 13, 2009

(30) Foreign Application Priority Data
Oct. 14, 2008 (JP) 2008-264983
Dec. 15, 2008 (JP) 2008-318833

(51) Int. Cl. H01L 23/498; H01L 21/60

(52) U.S. Cl. 257/778; 438/124; 257/737; 257/E21.511; 257/E23.06

(57) ABSTRACT

There is provided a flip-chip substrate which is flip-chip connected to electrode terminals provided on one surface of an electronic component. The flip-chip substrate includes: mounting pads which are exposed to a surface of the flip-chip substrate on which the electronic component is mounted and each of which comprises a pad surface which is flip-chip connected to a corresponding one of the electrode terminals; wiring patterns which are electrically connected to the mounting pads; an insulating layer which covers the wiring patterns; and a solder resist formed on an entire surface of the insulating layer such that each pad surface of the mounting pads is exposed from the solder resist.

This application claims priority from Japanese Patent Applications Nos. 2008-264983, filed on Oct. 14, 2008, and 2008-318833, filed on Dec. 15, 2008, the entire contents of which are incorporated by reference herein.

### BACKGROUND OF THE INVENTION

1. Technical Field

The present disclosure relates to a flip-chip substrate and a method of manufacturing the same, and more particularly, to a flip-chip substrate, which is connected to each of plural electrode terminals formed on one surface of chip-shaped electronic components by flip-chip bonding, and a method of manufacturing the same.

2. Related Art

In a semiconductor device such as chip-shaped electronic components, a substrate 100 shown in FIG. 8 has been known as a substrate which is connected in a flip-chip mounting manner to plural electrode terminals formed on one surface of the semiconductor device. The substrate 100 is made of resin and has mounting pads 106 which are formed on a semiconductor device surface of the substrate 100 and are connected in a flip-chip mounting manner to electrode terminals 104, 104, . . . of a semiconductor device 102, respectively. Patterns 108 are formed to extend from the mounting pads 106, 106, . . . , respectively. The patterns 108 are coated with a solder resist 110 covering the one surface of the substrate 100 except a pad surface of the mounting pads 106 connected in the flip-chip mounting manner to the electrode terminals 104, 104, . . . of the semiconductor device 102, respectively.

The mounting pads 106, 106, . . . are electrically connected to pads 114 on which solder balls 112 as external connection terminals formed on the other surface of the substrate 100 are mounted, through internal wirings such as the patterns 108 or vias formed in the substrate 100.

A surface of the other surface of the substrate 100 is also coated with the solder resist 110 except a pad surface of the pads 114 on which the solder balls 112 are mounted.

In the substrate 100 shown in FIG. 8, electrical isolation between the patterns 108 and 108 extending from the mounting pads 106, 106, . . . , respectively is made by the solder resist 110.

Patterning is carried out using the solder resist in order to form the patterns 108, 108, . . . . Such patterning is carried out through a photolithography process using the solder resist 110 containing a photosensitive agent or the like in order to improve patterning precision.

However, the insulating property of the solder resist 110 containing the photosensitive agent or the like is typically inferior to that of resin of an insulating layer forming the substrate 100.

To overcome this problem, JP-A-2008-140886 discloses a resin-made substrate 200 shown in FIG. 9. In this substrate 200, on a semiconductor device surface of the substrate 200, pillar-like mounting pads 206, which are respectively connected in a flip-chip mounting manner to electrode terminals 104, 104, . . . of a semiconductor device 102, are provided on pads 210 from which patterns 208 extend.

These mounting pads 206, patterns 208 and pads 210 are covered with an insulating layer forming the substrate 200 except a pad surface of the mounting pads 206 respectively connected in the flip-chip mounting manner to the electrode terminals 104, 104, . . . of the semiconductor device 102.

In addition, on the other surface of the substrate 200, pillar-like pads 216 for external connection terminals are formed on pads 214. The pads 214 are electrically connected to internal wirings such as the patterns 208 or vias formed in the substrate 200. The pads 216 and the pads 214 are covered with the insulting layer forming the substrate 200 except a pad surface on which solder balls 112 are mounted.

In the substrate 200 shown in FIG. 9, electrical isolation between adjacent mounting pads 206 and 206 formed on both surfaces of the substrate 200 can be made by the insulating layer. The insulating layer mainly forms the substrate 200 and has an insulating property superior to that of the solder resist 110. Thus, it is possible to improve reliability of the electrical insulating property of the substrate 200.

Also, in the substrate 200 shown in FIG. 9, when the semiconductor device 102 is mounted, the mounting pads 206, 206, . . . or alignment marks (not shown) prepared in a way similar to the mounting pads 206 are required to be recognized by a CCD camera or the like.

However, since a color or a color tone of the surface of the substrate 200, the pad surface of the mounting pads 206, 206, . . . or the alignment marks is different from that of the conventional substrate obtained using the solder resist, the mounting pads 206, 206, . . . or the alignment marks may be difficult to be recognized by a CCD camera or the like. Even in this case, the mounting pads 206, 206, . . . or the alignment marks may be recognized by adjusting the sensitivity or the like of the CCD camera.

However, if the conventional solder resist is greatly different from the insulating layer of the substrate 200, it may take a long time to adjust such a difference, which may lead to stoppage of the mounting operation of the semiconductor device 102 and hence deterioration of production efficiency of semiconductor apparatuses.

In general, after the electrode terminals 104, 104, . . . of the semiconductor device 102 are connected in the flip-chip mounting manner to the pad surface of the mounting pads 206 of the substrate 200, an underfill layer is formed by filling a gap between the semiconductor device 102 and the substrate 200 with an underfill material.

However, in some cases, adhesion between the underfill layer and the insulating layer of the substrate 200 may be insufficient, which may result in detachment of the underfill layer from the insulating layer.

### SUMMARY OF THE INVENTION

Exemplary embodiments of the present invention address the above disadvantages and other disadvantages not described above.

Accordingly, it is an aspect of the present invention to provide a flip-chip substrate which is capable of overcoming the problem of the related-art flip-chip substrate that the mounting pads are difficult to be recognized by a CCD camera or the like when electronic components are mounted and is capable of easily recognizing the mounting pads by the CCD camera or the like, and a method of manufacturing the same.

The present inventors have given careful consideration to the above problem and have made the present invention based on the discovery that a solder resist has various colors or color tones and mounting pads can be easily recognized by a CCD camera or the like by covering the entire surface of a substrate, except a pad surface of the mounting pads, with the solder resist.

According to one or more aspects of the present invention, there is provided a flip-chip substrate which is flip-chip connected to electrode terminals provided on one surface of an electronic component. The flip-chip substrate comprises: mounting pads which are exposed to a surface of the flip-chip substrate on which the electronic component is mounted and each of which comprises a pad surface which is flip-chip connected to a corresponding one of the electrode terminals; wiring patterns which are electrically connected to the mounting pads; an insulating layer which covers the wiring patterns; and a solder resist formed on an entire surface of the insulating layer such that each pad surface of the mounting pads is exposed from the solder resist.

According to one or more aspects of the present invention, there is provided a method of manufacturing a flip-chip substrate which is flip-chip connected to electrode terminals provided on one surface of a electronic component.

The method comprises: (a) forming mounting pads which are exposed to a surface of the flip-chip substrate on which the electronic component is mounted and each of which comprises a pad surface which is flip-chip connected to a corresponding one of the electrode terminals; (b) forming wiring patterns which are electrically connected to the mounting pads; (c) covering the mounting pads and the wiring patterns with an insulating layer; (d) exposing each pad surface of the mounting pads from the insulating layer; and (e) forming a solder resist on an entire surface of the insulating layer such that each pad surface of the mounting pads is exposed from the solder resist.

Other aspects and advantages of the invention will be apparent from the following description, the drawings and the claims.

### BRIEF DESCRIPTION OF THE DRAWINGS

FIG. 1 is a sectional view showing a flip-chip substrate according to an exemplary embodiment of the present invention;

FIGS. 2A to 2E are process views for explaining processes of manufacturing the flip-chip substrate of FIG. 1;

FIGS. 3A to 3D are process views for explaining the processes of manufacturing the flip-chip substrate of FIG. 1;

FIGS. 4A and 4B are process views for explaining the processes of manufacturing the flip-chip substrate of FIG. 1;

FIGS. 5A and 5B are partial sectional views for explaining different states of the pad surface of the mounting pad 24 and the solder resist 30 of the flip-chip substrate shown in FIG. 1;

FIGS. 6A and 6B are sectional views for explaining a flip-chip substrate according to another exemplary embodiment of the present invention;

FIGS. 7A and 7B are partial sectional views for explaining different states of the pad surface of the mounting pad 24 and the solder resist 30 of the flip-chip substrate shown in FIG. 6;

FIG. 8 is a sectional view showing a flip-chip substrate in the related art; and

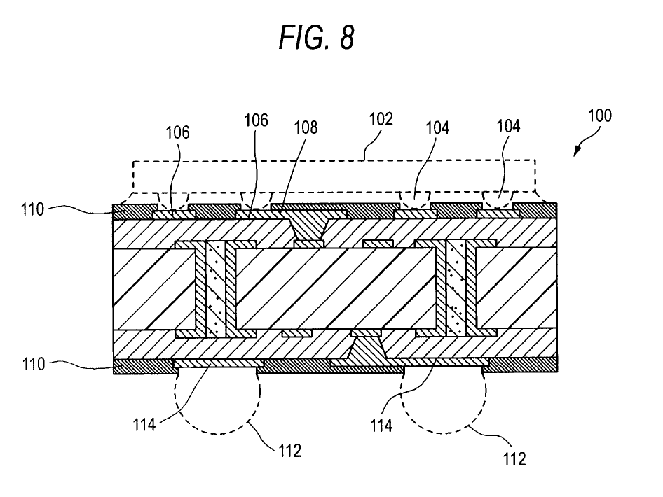

FIG. 9 is a sectional view showing an improved flip-chip substrate in the related art.

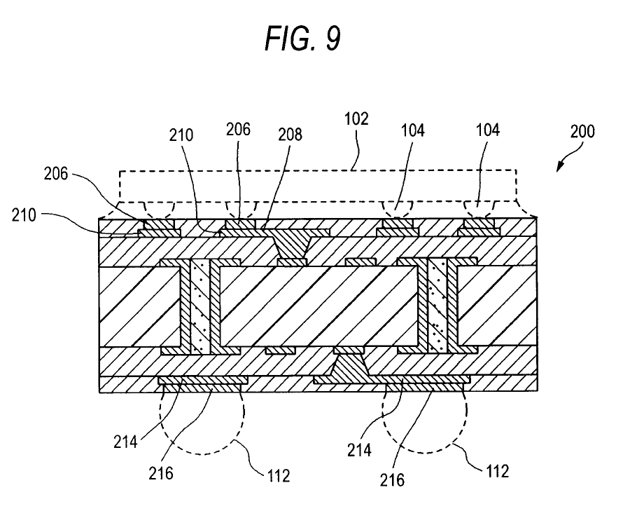

### DETAILED DESCRIPTION OF EXEMPLARY EMBODIMENTS

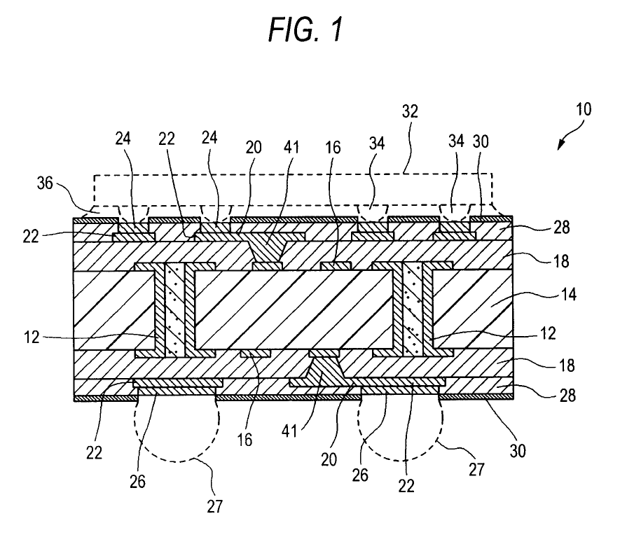

FIG. 1 shows a flip-chip substrate according to an exemplary embodiment of the present invention. A flip-chip substrate 10 (hereinafter sometimes referred to simply as substrate 10″) shown in FIG. 1 is a substrate on which a semiconductor device 32 as an electronic component is mounted.

The substrate 10 includes a resin-made core substrate 14 having patterns 16, 16, . . . formed on both surfaces thereof through through-holes 12, 12, . . . and also having patterns 20, 20, . . . formed on both surfaces thereof through a resin-made insulating layer 18. The patterns 20, 20, . . . are electrically connected to the patterns 16 through vias 41 or the like. Pads 22 are formed in one end of each of the patterns 20, 20, . . . .

Pillar-like mounting pads 24 (hereinafter sometimes referred to simply as “pads 24”) are provided on the pads 22, which are in a semiconductor device mounting surface of the substrate 10.

In addition, pillar-like pads 26 for external connection terminals (hereinafter sometimes referred to simply as “pads 26”) are provided on the pads 22, which are in a mounting surface of solder balls 27 serving as external connection terminals (in the other surface of the substrate 10).

These pads 22, patterns 20 and pillar-like pads 24 and 26 are covered with an insulating layer 28 made of resin having the same composition as that of the insulating layer 18 except the pad surface of the pads 24 and 26.

In this manner, since an additive having an adverse effect on an electrical insulating property, such as a photosensitive agent or the like, is not added to the resin forming the insulating layers 18 and 28 of the substrate 10, the electrical insulating property of the insulating layers 18 and 28 is good.

Accordingly, the insulating property between adjacent pads 24 and 24 and the insulating property between adjacent pads 26 and 26, which are covered with the insulating layers 18 and 28, is also good.

In addition, in the substrate 10 shown in FIG. 1, a surface of the uppermost insulating layer 28 at one surface of the substrate 10 is covered with a solder resist 30 except the pad surface of the pillar-like pads 24. The solder resist 30 has adhesion with the insulating layer 28 and shows a color or a color tone for allowing the pad surface of the pads 24 to be easily recognized by a CCD camera or the like.

In addition, the solder resist 30 also has an adhesion with an underfill layer 36 which fills a gap between the semiconductor device 32 and the substrate 10.

It is advantageous to pre-examine whether or not such a solder resist 30 has adhesion with the insulating layer 28 and the underfill layer 36 and shows a color or a color tone for allowing the pad surface of the pads 24 to be easily recognized by a CCD camera or the like used. For example, if the insulating layer 28 is made of thermosetting epoxy resin mixed with a filler and the underfill layer 36 is made of silicone-dispersed epoxy resin, it is advantageous that the solder resist 30 is made of bisphenol-type epoxy resin mixed with a filler.

In addition, in the substrate 10 shown in FIG. 1, a surface of the uppermost insulating layer 28 at the other surface of the substrate 10 is also covered by the solder resist 30 except the pad surface of the pillar-like pads 26.

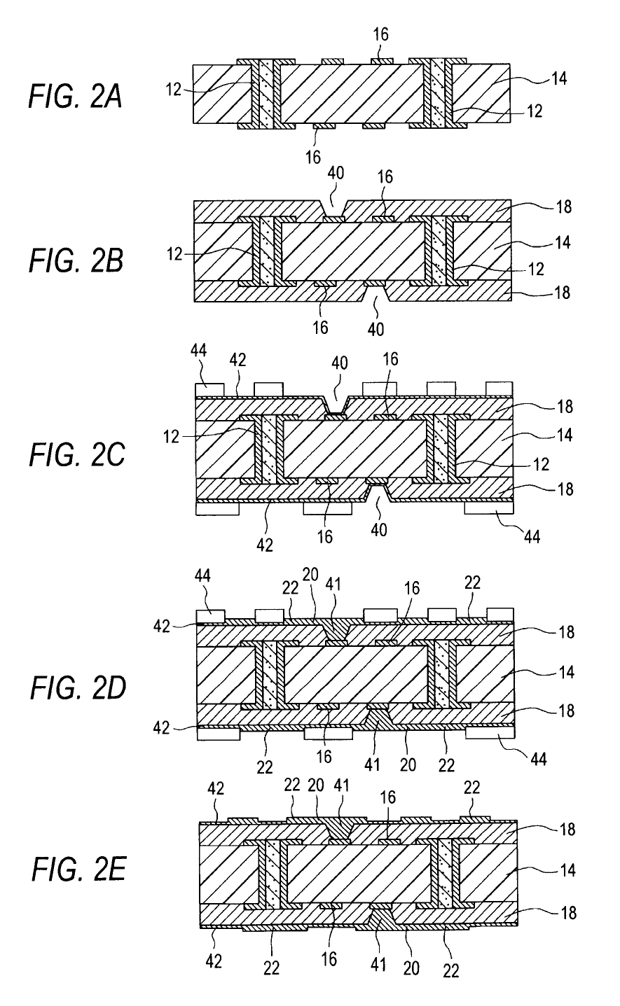

The core substrate 14 shown in FIG. 2A is used to manufacture the substrate 10 shown in FIG. 1. The core substrate 14 is made of resin and has the patterns 16, 16, . . . formed at both surfaces thereof.

As shown in FIG. 2B, the insulating layers 18, 18 are formed at both surfaces of the core substrate 14. The insulating layers 18, 18 are made of resin not having an additive which has an adverse effect on an electrical insulating property, such as a photosensitive agent. Concave portions 40, 40 for vias are formed in given portions of the insulating layers 18 and 18 by a laser. End portions of the patterns 16 are exposed in the bottom of the concave portions 40, 40.

A copper film layer 42 is formed in the entire surface including an inner wall of the concave portions 40, 40 of the insulating layers 18 and 18, as shown in FIG. 2C. The copper film layer 42 may be formed by electroless copper plating or sputtering.

Photosensitive resin 44 is patterned on the copper film layer 42 such that the copper film layer 42 is exposed to the bottom of a portion forming a pattern or a pad, as shown in FIG. 2C. Then, the patterns 20, the vias 41 and the pads 22 are formed by electrolytic copper plating using the copper film layer 42 as a power feed layer, as shown in FIG. 2D.

In addition, as shown in FIG. 2E, the photosensitive resin 44 is removed to expose the copper film layer 42 which interconnects the patterns 20 and the pads 22.

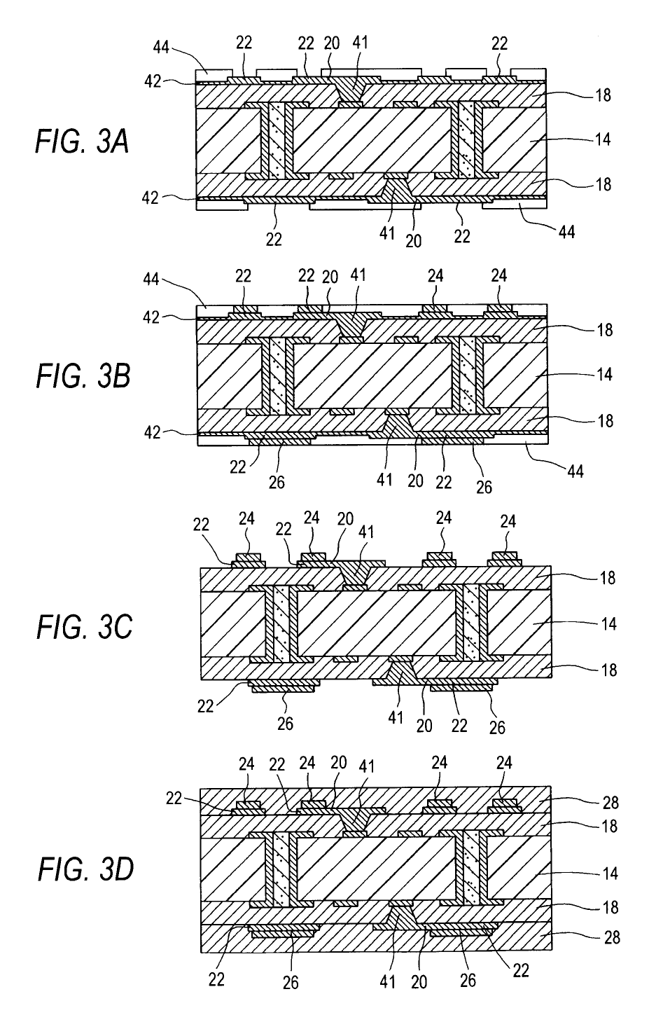

Subsequently, as shown in FIG. 3A, the photosensitive resin 44 is patterned to form pads which are provided on the pad 22. A concave portion in which the pads 22 are exposed is formed in a portion in which the pads are provided.

Since the pads 22 and the patterns 20 are electrically connected to each other through the copper film layer 42, the mounting pads 24 and the external connection terminal pads 26 provided on the pads 22 may be formed by electrolytic copper plating using the copper film layer 42 as a power feed layer, as shown in FIG. 3B.

In addition, after removing the photosensitive resin 44, the copper film layer 42 is etched away. Thus, electrical isolation between adjacent mounting pads 24 and 24, electrical isolation between adjacent external connection terminal pads 26 and electrical isolation between adjacent patterns 20 and 20 may be ensured, as shown in FIG. 3C.

In this manner, the mounting pads 24, pads 22 and patterns 20 formed on one surface of the core substrate 14 and the external connection terminal pads 26, pads 22 and patterns 20 formed on the other surface of the core substrate 14 are covered with the insulating layers 28 and 28, as shown in FIG. 3D. These insulating layers 28 and 28 are made of resins having the same composition as the resin forming the insulating layer 18.

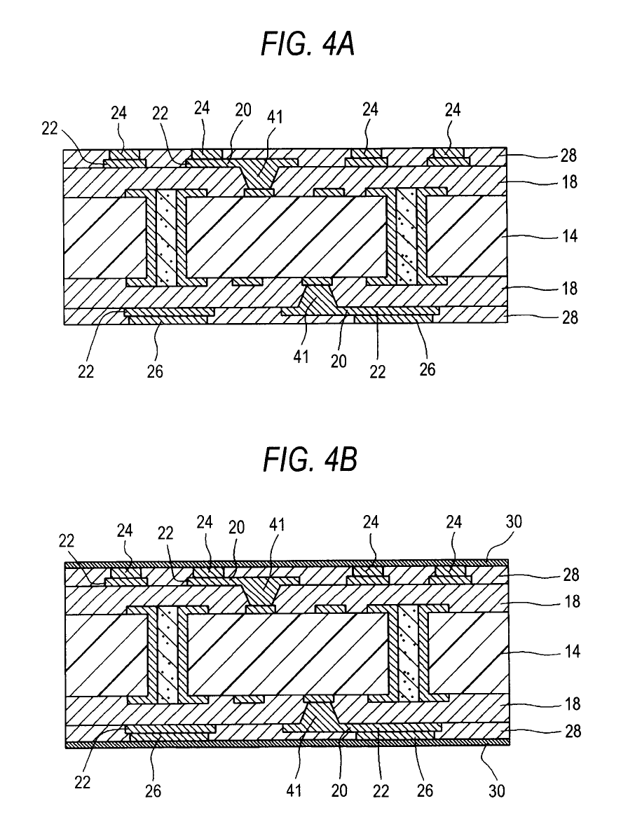

In addition, the entire surface of the insulating layers 28, 28 is subjected to sandblasting, so that end surfaces of the mounting pads 24 and the external connection terminal pads 26 can be exposed from the insulating layers 28, 28, as shown in FIG. 4A.

Thereafter, as shown in FIG. 4B, the entire surface of the insulating layers 28, 28, including the mounting pads 24, is covered with the solder resists 30, 30. The solder resists 30, 30 are patterned to expose the end surfaces of the mounting pads 24 and the external connection terminal pads 26. Thus, the substrate 10 can be formed as shown in FIG. 1.

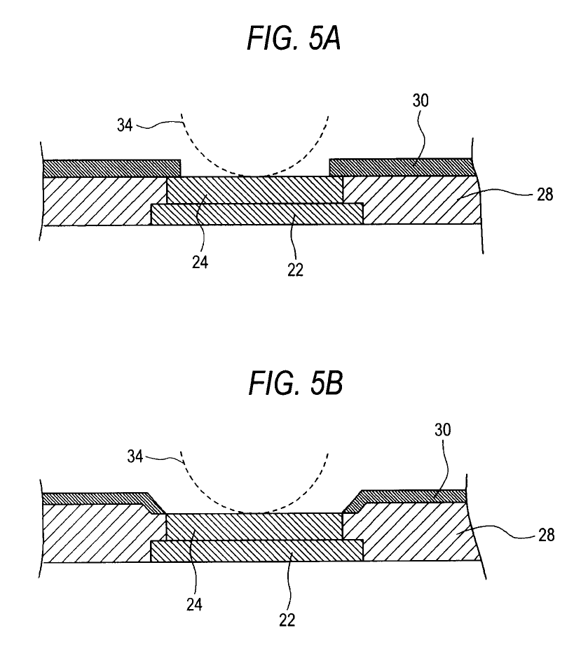

Although the entire surface of the end surface of the mounting pad 24 is exposed from the solder resist 30 as shown in FIG. 1, an end portion of the solder resist 30 may extend to the end surface of the mounting pad 24, and thus a pad surface connected to the electrode terminal 34 may be narrowed to conform to the size of the electrode terminal 34 of the semiconductor device 32, as shown in FIG. 5A.

In addition, as shown in FIG. 5B, if the end surface of the mounting pad 24 is exposed to the bottom of a tapered concave portion formed in the insulating layer 28, a side of the tapered concave portion can be coated with the solder resist 30. Thus, it is advantageous in light of adhesion with the underfill layer 36.

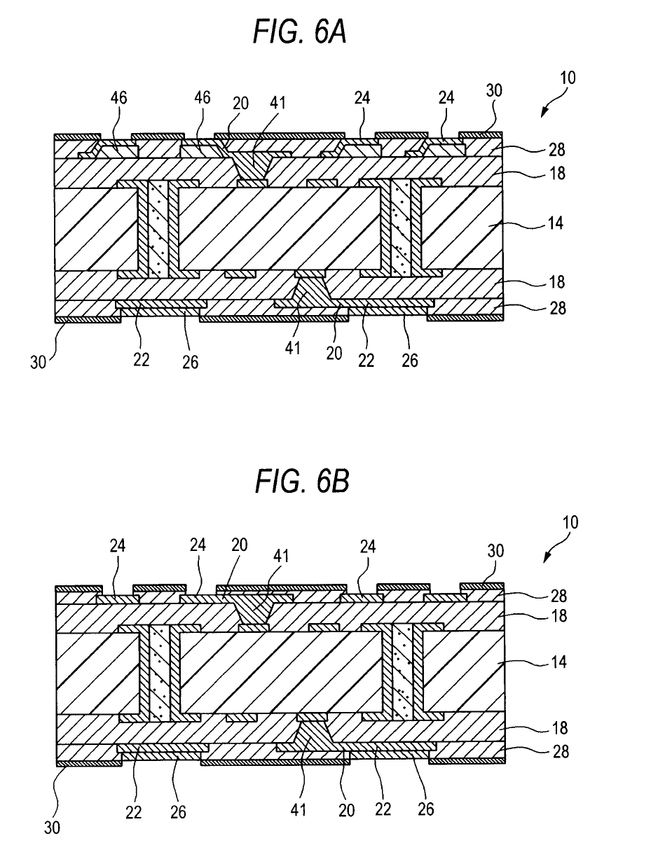

Although the pillar-like mounting pads 24, 24 . . . are formed on the pads 22 in the substrate 10 shown in FIG. 1, this substrate may be replaced with a substrate 10 shown in FIG. 6A. In the substrate 10 shown in FIG. 6A, resin-made projections 46 are formed on the surface of the insulating layer 18. The projections 46 each have an inclined side wall and a flat top side. The pattern 20 is formed along the inclined side wall of the projection 46 and is connected to the mounting pad 24 formed on the top side of the projection 46. The pattern 20 has the same thickness as the mounting pad 24.

In addition, in the substrate 10 shown in FIG. 6A, the projections 46, the patterns 20 and the like are covered with the insulating layer 28, and only the pad surface of the mounting pads 24, 24, . . . is exposed from the insulating layer 28 and the solder resist 30.

Alternatively, a substrate 10 shown in FIG. 6B may be employed. In the substrate 10 shown in FIG. 6B, patterns 20 and mounting pads 24 connected to the patterns 20 may be formed on the same plane as the insulating layer 18. While the patterns 20 are covered with the insulating layer 28 covering the insulating layer 18, the end surface of the mounting pads 24, 24, . . . is exposed from the insulating layer 28 and the solder resist 30.

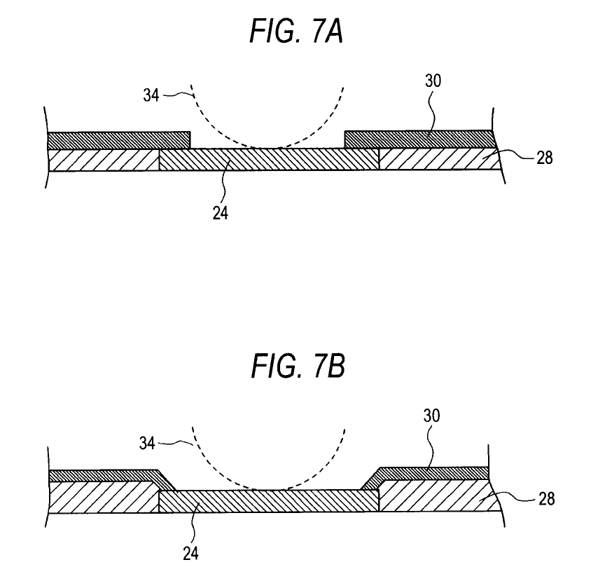

Also in the substrate 10 shown in FIGS. 6A and 6B, an end portion of the solder resist 30 may extend to the end surface of the mounting pad 24, and thus a pad surface connected to the electrode terminal 34 may be narrowed to conform to the size of the electrode terminal 34 of the semiconductor device 32, as shown in FIG. 7A.

In addition, as shown in FIG. 7B, if the end surface of the mounting pad 24 is exposed to the bottom of a tapered concave portion formed in the insulating layer 28, a side surface of the tapered concave portion can be coated with the solder resist 30. Thus, it is advantageous in light of adhesion with the underfill layer 36.

In the above-described substrates 10, a shape of the pad surface exposed from the solder resist 30 of the mounting pads 24 may be circular or rectangular.

In addition, when the insulating layers 28, 28 are ground to expose the end surfaces of the mounting pads 24 and the external connection terminal pads 26, the insulating layers 28 and 28 may be ground by a grinder instead of sandblast.

In addition, when the end surfaces of the mounting pads 24 and the external connection terminal pads 26 are exposed from the solder resist, instead of partial sandblast, a solder resist containing a photosensitive agent may be used to expose the end surfaces of the mounting pads 24 and the external connection terminal pads 26 from the solder resists 30, 30 through exposure and development.

Here, while an electrical insulating property of the solder resist containing the photosensitive agent is lower than those of the insulating layers 18 and 28, electrical insulation between adjacent mounting pads 24, 24 is made by the insulating layers 18 and 28 without causing any problem regarding an electrical insulating property.

In addition, while exemplary embodiments of the present invention are applied to both surfaces of the substrates 10 shown in FIGS. 1 to 7, the exemplary embodiments may be applied to only the semiconductor device mounting surface of the substrates 10.

Also, in the exemplary embodiments, the semiconductor device 32 is mounted as an electronic component on the substrates 10. However, other electronic components such as other semiconductor devices, capacitors, resistors and the like may be mounted on the substrates 10.

In the flip-chip substrate according to the present invention, the mounting pads formed on the surface of the flip-chip substrate on which the electronic component is mounted are electrically isolated from each other by the insulating layer. Since the electrical insulating property of the insulating layer is typically superior to that of the solder resist, an electrical insulating property between the mounting pads can be improved.

Furthermore, the entire surface of the insulating layer except the pad surface of the mounting pads is covered with the solder resist. Accordingly, by using a solder resist for allowing the mounting pads to be easily recognized by a CCD camera, efficiency of mounting electronic components on the substrate can be improved without adjustment of sensitivity of the CCD camera or the like.

While the present invention has been shown and described with reference to certain example embodiments, other implementations are within the scope of the claims. It will be understood by those skilled in the art that various changes in form and details may be made therein without departing from the spirit and scope of the invention as defined by the appended claims.

What is claimed is:

1. A flip-chip substrate which is flip-chip connected to electrode terminals provided on one surface of an electronic component, the flip-chip substrate comprising:
mounting pads which are exposed to a surface of the flip-chip substrate on which the electronic component is mounted and each of which comprises a pad surface which is flip-chip connected to a corresponding one of the electrode terminals;
wiring patterns which are electrically connected to the mounting pads;
an insulating layer which covers the wiring patterns; and
a solder resist formed on an entire surface of the insulating layer such that each pad surface of the mounting pads is exposed from the solder resist.

2. The flip-chip substrate according to claim 1,
wherein the insulating layer is made of an insulating resin which contains no photosensitive agent.

3. The flip-chip substrate according to claim 1,
wherein the electronic component is a semiconductor device, and
wherein the solder resist has an adhesion with an underfill layer, the underfill layer being filled in a gap between the insulating layer and the semiconductor device.

4. A method of manufacturing a flip-chip substrate, the flip-chip substrate being flip-chip connected to electrode terminals provided on one surface of a electronic component, the method comprising:
(a) forming mounting pads which are exposed to a surface of the flip-chip substrate on which the electronic component is mounted and each of which comprises a pad surface which is flip-chip connected to a corresponding one of the electrode terminals;
(b) forming wiring patterns which are electrically connected to the mounting pads;
(c) covering the mounting pads and the wiring patterns with an insulating layer;
(d) exposing each pad surface of the mounting pads from the insulating layer; and
(e) forming a solder resist on an entire surface of the insulating layer such that each pad surface of the mounting pads is exposed from the solder resist.

5. The method according to claim 4,
wherein the insulating layer is made of an insulating resin which contains no photosensitive agent.

6. The method according to claim 4, wherein step (d) comprises:
exposing each pad surface of the mounting pads from the insulating layer by sandblast.

7. The method according to claim 4,
wherein the electronic component is a semiconductor device, and
wherein the solder resist has an adhesion with an underfill layer, the underfill layer being filled in a gap between the insulating layer and the semiconductor device.
